(19) United States
(12) Patent Application Publication
(10) Pub. No.: US 2021/0136909 A1
(43) Pub. Date: May 6, 2021

(54) INTERPOSER BOARD HAVING HEATING FUNCTION AND ELECTRONIC DEVICE

(71) Applicant: ASTI GLOBAL INC., TAIWAN, Taichung City (TW)

(72) Inventors: CHIEN-SHOU LIAO, New Taipei City (TW); TE-FU CHANG, Taichung City (TW)

(21) Appl. No.: 16/891,290

(22) Filed: Jun. 3, 2020

(30) Foreign Application Priority Data
Nov. 6, 2019 (TW) 108140260

(51) Int. Cl. H05K 1/02; H05K 3/34

(52) U.S. Cl. CPC H05K 1/0212; H05K 3/3494; H05K 3/3415; H05K 1/0213

(57) ABSTRACT

An interposer board having heating function and an electronic device using the same are provided. The interposer board includes an insulating body, a plurality of top conductive contacts, a plurality of bottom conductive contacts, a plurality of conductive connection structures and a plurality of micro heaters. The top conductive contacts are disposed on the insulating body. The bottom conductive contacts are disposed on the insulating body. The conductive connection structures are disposed on the insulating body, and the conductive connection structures respectively electrically connected to the top conductive contacts and respectively electrically connected to the bottom conductive contacts. The micro heaters are disposed on or in the insulating body, and the micro heaters are respectively adjacent to the top conductive contacts and the bottom conductive contacts. Each of the top conductive contacts or each of the bottom conductive contacts can be heated by the corresponding micro heater.

### CROSS-REFERENCE TO RELATED PATENT APPLICATION

This application claims the benefit of priority to Taiwan Patent Application No. 108140260, filed on Nov. 6, 2019. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an interposer board and an electronic device, and more particularly to an interposer board having heating function and an electronic device using the same.

### BACKGROUND OF THE DISCLOSURE

Currently, an IC chip can be electrically connected to a PCB through an interposer board, but the conventional interposer board still has room for improvement.

### SUMMARY OF THE DISCLOSURE

In response to the above-referenced technical inadequacies, the present disclosure provides an interposer board having heating function and an electronic device using the same.

In one aspect, the present disclosure provides an interposer board having heating function, including an insulating body, a plurality of top conductive contacts, a plurality of bottom conductive contacts, a plurality of conductive connection structures and a plurality of micro heaters. The top conductive contacts are disposed on a top side of the insulating body. The bottom conductive contacts are disposed on a bottom side of the insulating body. The conductive connection structures are disposed inside the insulating body. The conductive connection structures are respectively electrically connected to the top conductive contacts and respectively electrically connected to the bottom conductive contacts so as to electrically connect each of the conductive connection structures between the corresponding top conductive contact and the corresponding bottom conductive contact. The micro heaters are disposed on or in the insulating body, and the micro heaters are respectively adjacent to the top conductive contacts and the bottom conductive contacts. When a plurality of top solders are respectively disposed on the top conductive contacts and a plurality of bottom solders are respectively disposed on the bottom conductive contacts, the top solders and the bottom solders are heated by the micro heaters.

In another aspect, the present disclosure provides an interposer board having heating function, including an insulating body, a plurality of top conductive contacts, a plurality of bottom conductive contacts, a plurality of conductive connection structures and a plurality of micro heaters. The top conductive contacts are disposed on the insulating body. The bottom conductive contacts are disposed on the insulating body. The conductive connection structures are disposed on the insulating body, and the conductive connection structures respectively electrically connected to the top conductive contacts and respectively electrically connected to the bottom conductive contacts. The micro heaters are disposed on or in the insulating body, and the micro heaters are respectively adjacent to the top conductive contacts and the bottom conductive contacts. Each of the top conductive contacts or each of the bottom conductive contacts is heated by the corresponding micro heater.

In yet another aspect, the present disclosure provides an electronic device includes a circuit substrate, an interposer board disposed on the circuit substrate, and at least one electronic chip been carried by the interposer board. The interposer board includes an insulating body, a plurality of top conductive contacts, a plurality of bottom conductive contacts, a plurality of conductive connection structures and a plurality of micro heaters. The top conductive contacts are disposed on the insulating body. The bottom conductive contacts are disposed on the insulating body. The conductive connection structures are disposed on the insulating body, and the conductive connection structures respectively electrically connected to the top conductive contacts and respectively electrically connected to the bottom conductive contacts. The micro heaters are disposed on or in the insulating body, and the micro heaters are respectively adjacent to the top conductive contacts and the bottom conductive contacts. Each of the top conductive contacts or each of the bottom conductive contacts is heated by the corresponding micro heater.

Therefore, by virtue of “the micro heaters being disposed on or in the insulating body” and “the micro heaters being respectively adjacent to the top conductive contacts and the bottom conductive contacts”, each of the top conductive contacts or each of the bottom conductive contacts can be heated by the corresponding micro heater. Whereby, when a plurality of top solders are respectively disposed on the top conductive contacts and a plurality of bottom solders are respectively disposed on the bottom conductive contacts, the top solders and the bottom solders can be heated by the micro heaters.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a schematic view of an interposer board having heating function according to a first embodiment of the present disclosure.

FIG. 2 is a function block of the relationship between a first top power input contact and a top micro heater according to the first embodiment of the present disclosure.

FIG. 3 is a function block of the relationship between the bottom power input contact and the bottom micro heater according to the first embodiment of the present disclosure.

FIG. 4 is a schematic view of an interposer board having heating function according to a second embodiment of the present disclosure.

FIG. 5 is an exploded schematic view of an electronic device according to a third embodiment of the present disclosure.

FIG. 6 is an assembled schematic view of the electronic device according to the third embodiment of the present disclosure.

FIG. 7 is a top schematic view of the electronic device according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

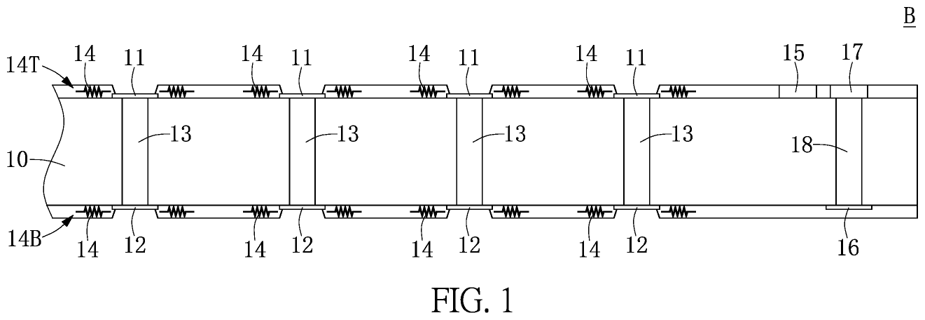

Referring to FIG. 1 to FIG. 3, a first embodiment of the present disclosure provides an interposer board B having heating function, including an insulating body 10, a plurality of top conductive contacts 11, a plurality of bottom conductive contacts 12, a plurality of conductive connection structures 13 and a plurality of micro heaters 14.

More particularly, as shown in FIG. 1, the top conductive contacts 11 are disposed on the insulating body 10, and the bottom conductive contacts 12 also are disposed on the insulating body 10. In addition, the conductive connection structures 13 are disposed on or in the insulating body 10, and the conductive connection structures 13 are respectively electrically connected to the top conductive contacts 11 and respectively electrically connected to the bottom conductive contacts 12. Moreover, the micro heaters 14 are disposed on the insulating body 10, and the micro heaters 14 are respectively adjacent to the top conductive contacts 11 and the bottom conductive contacts 12. Therefore, each of the top conductive contacts 11 or each of the bottom conductive contacts 12 can be heated by the corresponding micro heater 14. That is to say, each micro heater 14 can be used to heat the corresponding top conductive contact 11 or the corresponding bottom conductive contact 12.

For example, as shown in FIG. 1, the top conductive contacts 11 can be disposed on a top side of the insulating body 10, and the bottom conductive contacts 12 can be disposed on a bottom side of the insulating body 10. In addition, the conductive connection structures 13 can be disposed inside the insulating body 10, the conductive connection structure 13 may be a straight or non-straight conductive connection body, and the conductive connection structure 13 has two opposite sides respectively electrically connected to the top conductive contact 11 and the bottom conductive contact 12. That is to say, when the conductive connection structures 13 are respectively electrically connected to the top conductive contacts 11 and respectively electrically connected to the bottom conductive contacts 12, each of the conductive connection structures 13 can be electrically connected between the corresponding top conductive contact 11 and the corresponding bottom conductive contact 12. However, the aforementioned description is merely an example and is not meant to limit the scope of the present disclosure.

For example, the micro heater 14 can be made as a conductive coil structure, and each micro heater 14 can correspond to one of the top conductive contacts 11 or one of the bottom conductive contacts 12. Moreover, the micro heater 14 may be a surrounding micro heater for surrounding the corresponding top conductive contact 11 or the corresponding bottom conductive contacts 12; or the micro heater 14 can also be arranged on any three sides beside the corresponding top conductive contact 11 or any three sides beside the corresponding bottom conductive contacts 12; or the micro heater 14 can also be arranged on any two sides beside the corresponding top conductive contact 11 or any two sides beside the corresponding bottom conductive contacts 12 (as shown in FIG. 1); or the micro heater 14 can also be arranged on any one side beside the corresponding top conductive contact 11 or any one side beside the corresponding bottom conductive contacts 12. In addition, the micro heaters 14 are in series connection with each other, in parallel connection with each other, or in series and parallel connection with each other. However, the aforementioned description is merely an example and is not meant to limit the scope of the present disclosure.

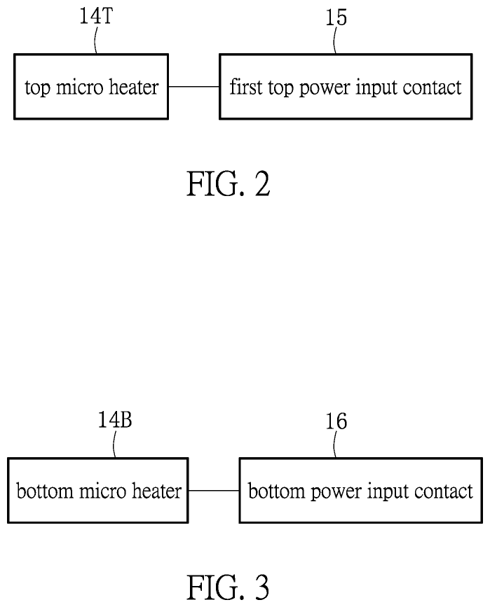

Moreover, referring to FIG. 1 to FIG. 3, the interposer board B of the first embodiment of the present disclosure further includes a plurality of first top power input contacts 15, a plurality of bottom power input contacts 16 and a plurality of second top power input contacts 17. More particularly, the first top power input contacts 15 are disposed on the top side of the insulating body 10, and each of the first top power input contacts 15 is electrically connected to at least one of the top micro heaters 14T (as shown in FIG. 2). In addition, the bottom power input contacts 16 are disposed on the bottom side of the insulating body 10, and each of the bottom power input contacts 16 is electrically connected to at least one of the bottom micro heaters 14B (as shown in FIG. 3). Moreover, the second top power input contacts 17 are disposed on the top side of the insulating body 10, the second top power input contacts 17 respectively correspond to the bottom power input contacts 16, and each of the second top power input contacts 17 is electrically connected to the corresponding bottom power input contact 16 through a conductive channel 18. That is to say, the first top power input contacts 15 and the second top power input contacts 17 are disposed on the top side of the insulating body 10, so that it is convenient for a user to input power into the first top power input contacts 15 and the second top power input contacts 17 from the top side of the insulating body 10 so as to turn on each micro heater 14 to heat the corresponding top conductive contact 11 or the corresponding bottom conductive contact 12. For example, each of the first top power input contacts 15 may include a positive contact and a negative contact, and each of the second top power input contacts 17 may include a positive contact and a negative contact. However, the aforementioned description is merely an example and is not meant to limit the scope of the present disclosure.

### Second Embodiment

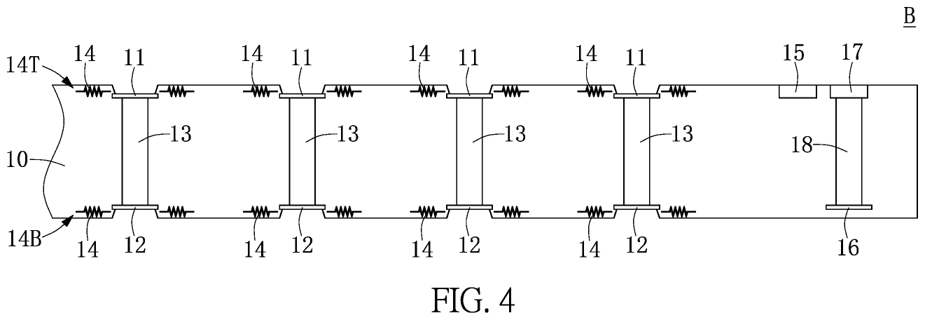

Referring to FIG. 4, a second embodiment of the present disclosure provides an interposer board B having heating function, including an insulating body 10, a plurality of top conductive contacts 11, a plurality of bottom conductive contacts 12, a plurality of conductive connection structures 13 and a plurality of micro heaters 14. Comparing FIG. 4 with FIG. 1, the difference between the second embodiment and the first embodiment is as follows: in the second embodiment, the micro heaters 14 are disposed inside the insulating body 10. For example, a micro heater film with a plurality of micro heaters 14 can be manufactured in advance, and then the micro heater film with the plurality of micro heaters 14 can be disposed on the top side or the bottom side of the insulating body 10 (such as in the first embodiment as shown in FIG. 1), or a plurality of micro heaters 14 can be directly embedded into the insulating body 10 when manufacturing the insulating body 10 (shown as the second embodiment in FIG. 4). However, the aforementioned description for the arrangement of the micro heaters 14 in the first embodiment or the second embodiment is merely an example and is not meant to limit the scope of the present disclosure.

### Third Embodiment

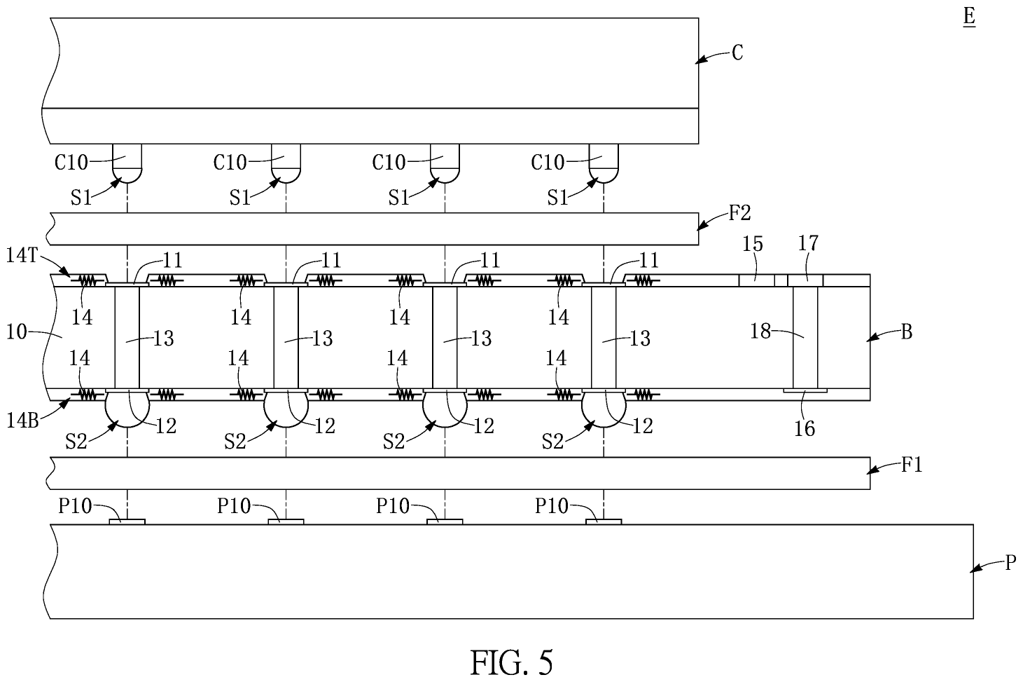

Referring to FIG. 5 to FIG. 7, a third embodiment of the present disclosure provides an electronic device E including a circuit substrate P, an interposer board B disposed on the circuit substrate P, and at least one electronic chip C that is carried by the interposer board B. The interposer board B includes an insulating body 10, a plurality of top conductive contacts 11, a plurality of bottom conductive contacts 12, a plurality of conductive connection structures 13 and a plurality of micro heaters 14.

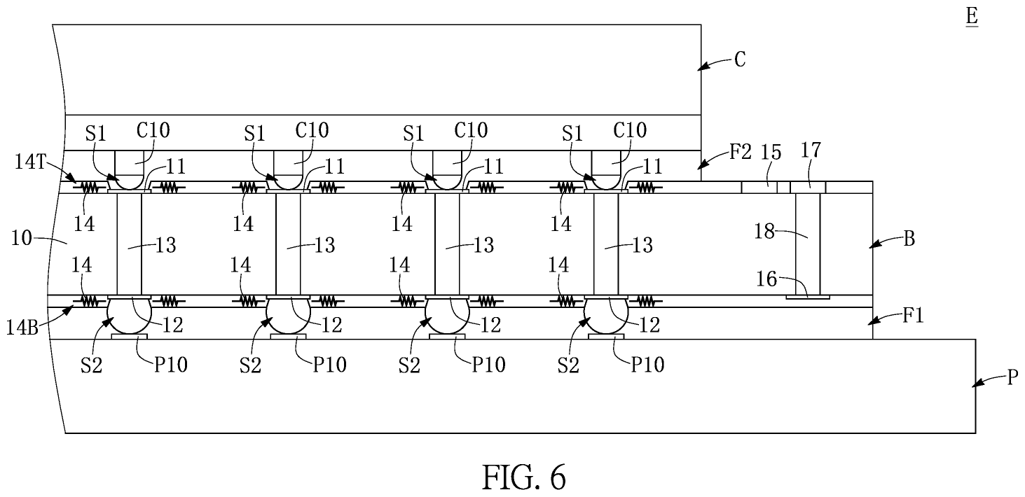

More particularly, referring to FIG. 5 and FIG. 6, the insulating body 10 is disposed on the circuit substrate P, the top conductive contacts 11 are disposed on the insulating body 10, and the bottom conductive contacts 12 are also disposed on the insulating body 10. In addition, the conductive connection structures 13 are disposed on or in the insulating body 10, and the conductive connection structures 13 are respectively electrically connected to the top conductive contacts 11 and respectively electrically connected to the bottom conductive contacts 12. Moreover, the micro heaters 14 are disposed on the insulating body 10, the micro heaters 14 are respectively adjacent to the top conductive contacts 11 and the bottom conductive contacts 12, and each of the top conductive contacts 11 or each of the bottom conductive contacts 12 can be heated by the corresponding micro heater 14. Therefore, when a plurality of top solders S1 are respectively disposed on the top conductive contacts 11 and a plurality of bottom solders S2 are respectively disposed on the bottom conductive contacts 12, the top solders S1 and the bottom solders S2 can be heated by the micro heaters 14, so that the at least one electronic chip C can be positioned on the interposer board B by heating the top solders S1, and the interposer board B can be positioned on the circuit substrate P by heating the bottom solders S2. For example, the top solders S1 and the bottom solders S2 may be solder balls, solder pastes or any conductive materials for bonding the at least one electronic chip C. However, the aforementioned description for the top solders S1 and the bottom solders S2 is merely an example and is not meant to limit the scope of the present disclosure.

More particularly, referring to FIG. 5 and FIG. 6, when the insulating body 10 is disposed on the circuit substrate P for carrying the at least one electronic chip C, the at least one electronic chip C can be electrically connected to the circuit substrate P through the interposer board B. Whereby, the bottom conductive contacts 12 can be respectively electrically connected to a plurality of conductive substrate contacts P10 of the circuit substrate P respectively through the bottom solders S2, and the top conductive contacts 11 are respectively electrically connected to a plurality of conductive chip contacts C10 of the at least one electronic chip C respectively through the top solders S1.

More particularly, referring to FIG. 5 and FIG. 6, the electronic device E of the third embodiment of the present disclosure further includes a first non-conductive film F1 (or a first non-conductive paste such as an underfill) and a second non-conductive film F2 (or a second non-conductive paste such as an underfill). When the first non-conductive film F1 is disposed between the insulating body 10 and the circuit substrate P, and the second non-conductive film F2 is disposed between the at least one electronic chip C and the insulating body 10, the micro heaters 14 can be used to heat the first non-conductive film F1 and the second non-conductive film F2 (that is to say, the first non-conductive film F1 and the second non-conductive film F2 can be heated by driving the micro heaters 14). Whereby, the first non-conductive film F1 can be firmly positioned between the insulating body 10 and the circuit substrate P by heating so as to fill gaps between the insulating body 10 and the circuit substrate P with the first non-conductive film F1, and the second non-conductive film F2 can be firmly positioned between the at least one electronic chip C and the insulating body 10 by heating so as to fill gaps between the at least one electronic chip C and the insulating body 10 with the second non-conductive film F2. For example, when the first non-conductive film F1 and the second non-conductive film F2 are heated by the micro heaters 14, the first non-conductive film F1 and the second non-conductive film F2 are deformed due to heating, so that the gaps formed between the insulating body 10 and the circuit substrate P can be fully filled with the first non-conductive film F1 and the gaps formed between the at least one electronic chip C and the insulating body 10 can be fully filled with the second non-conductive film F2.

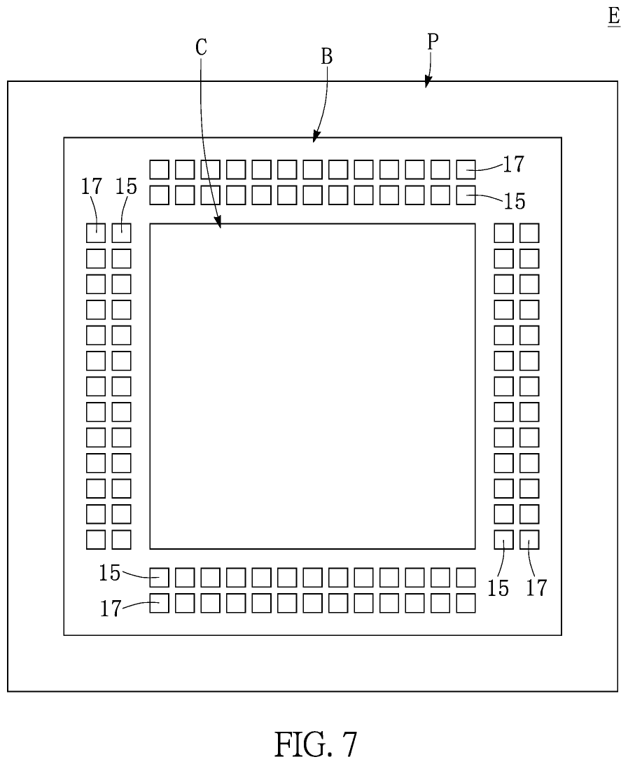

It should be noted that when the micro heaters 14 are divided into a plurality of top micro heaters 14T and a plurality of bottom micro heaters 14B as shown in FIG. 6, the top micro heater 14T is closer to the at least one electronic chip C than the bottom micro heater 14B is, and the bottom micro heater 14B is closer to the circuit substrate P than the top micro heater 14T is. Referring to FIG. 6 and FIG. 7, the second top power input contacts 17 can be disposed on the top side of the insulating body 10, the second top power input contacts 17 can respectively correspond to the bottom power input contacts 16, and each of the second top power input contacts 17 can be electrically connected to the corresponding bottom power input contact 16 through a conductive channel 18. That is to say, the first top power input contacts 15 and the second top power input contacts 17 can be disposed on the top side of the insulating body 10, so that it is convenient for a user to input power into the first top power input contacts 15 and the second top power input contacts 17 from the top side of the insulating body 10 so as to turn on each micro heater 14 to heat the corresponding top conductive contact 11 or the corresponding bottom conductive contact 12.

In conclusion, by virtue of “the micro heaters 14 being disposed on or in the insulating body 10” and “the micro heaters 14 being respectively adjacent to the top conductive contacts 11 and the bottom conductive contacts 12”, each of the top conductive contacts 11 or each of the bottom conductive contacts 12 can be heated by the corresponding micro heater 14. Whereby, when a plurality of top solders S1 are respectively disposed on the top conductive contacts 11 and a plurality of bottom solders S2 are respectively disposed on the bottom conductive contacts 12, the top solders S1 and the bottom solders S2 can be heated by the micro heaters 14.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An interposer board having heating function, comprising:
an insulating body;
a plurality of top conductive contacts disposed on a top side of the insulating body;
a plurality of bottom conductive contacts disposed on a bottom side of the insulating body;
a plurality of conductive connection structures disposed inside the insulating body, the conductive connection structures respectively electrically connected to the top conductive contacts and respectively electrically connected to the bottom conductive contacts so as to electrically connect each of the conductive connection structures between the corresponding top conductive contact and the corresponding bottom conductive contact; and
a plurality of micro heaters disposed on or in the insulating body, wherein the micro heaters are respectively adjacent to the top conductive contacts and the bottom conductive contacts;
wherein when a plurality of top solders are respectively disposed on the top conductive contacts and a plurality of bottom solders are respectively disposed on the bottom conductive contacts, the top solders and the bottom solders are heated by the micro heaters.

2. The interposer board according to claim 1, wherein when the insulating body is disposed on a circuit substrate for carrying at least one electronic chip, a first non-conductive film is disposed between the insulating body and the circuit substrate, and a second non-conductive film is disposed between the at least one electronic chip and the insulating body; wherein the at least one electronic chip is electrically connected to the circuit substrate through the interposer board, and the first non-conductive film and the second non-conductive film are heated by the micro heaters; wherein the bottom conductive contacts are respectively electrically connected to a plurality of conductive substrate contacts of the circuit substrate respectively through the bottom solders, and the top conductive contacts are respectively electrically connected to a plurality of conductive chip contacts of the at least one electronic chip respectively through the top solders; wherein the conductive connection structure is a straight or non-straight conductive connection body, and the conductive connection structure has two opposite sides respectively electrically connected to the top conductive contact and the bottom conductive contact; wherein the micro heaters are divided into a plurality of top micro heaters and a plurality of bottom micro heaters, the top micro heater is closer to the at least one electronic chip than the bottom micro heater is, and the bottom micro heater is closer to the circuit substrate than the top micro heater is.

3. The interposer board according to claim 2, further comprising:
a plurality of first top power input contacts disposed on the top side of the insulating body, each of the first top power input contacts being electrically connected to at least one of the top micro heaters;
a plurality of bottom power input contacts disposed on the bottom side of the insulating body, each of the bottom power input contacts being electrically connected to at least one of the bottom micro heaters; and
a plurality of second top power input contacts disposed on the top side of the insulating body, each of the second top power input contacts electrically connected to the corresponding bottom power input contact through a conductive channel

4. An interposer board having heating function, comprising:
an insulating body;
a plurality of top conductive contacts disposed on the insulating body;
a plurality of bottom conductive contacts disposed on the insulating body;
a plurality of conductive connection structures disposed on the insulating body, the conductive connection structures respectively electrically connected to the top conductive contacts and respectively electrically connected to the bottom conductive contacts; and
a plurality of micro heaters disposed on or in the insulating body, wherein the micro heaters are respectively adjacent to the top conductive contacts and the bottom conductive contacts;
wherein each of the top conductive contacts or each of the bottom conductive contacts is heated by the corresponding micro heater.

5. The interposer board according to claim 4, wherein when the insulating body is disposed on a circuit substrate for carrying at least one electronic chip, a first non-conductive film is disposed between the insulating body and the circuit substrate, and a second non-conductive film is disposed between the at least one electronic chip and the insulating body; wherein the at least one electronic chip is electrically connected to the circuit substrate through the interposer board, and the first non-conductive film and the second non-conductive film are heated by the micro heaters; wherein the bottom conductive contacts are respectively electrically connected to a plurality of conductive substrate contacts of the circuit substrate respectively through the bottom solders, and the top conductive contacts are respectively electrically connected to a plurality of conductive chip contacts of the at least one electronic chip respectively through the top solders; wherein the conductive connection structure is a straight or non-straight conductive connection body, and the conductive connection structure has two opposite sides respectively electrically connected to the top conductive contact and the bottom conductive contact; wherein the micro heaters are divided into a plurality of top micro heaters and a plurality of bottom micro heaters, the top micro heater is closer to the at least one electronic chip than the bottom micro heater is, and the bottom micro heater is closer to the circuit substrate than the top micro heater is.

6. The interposer board according to claim 5, further comprising:
a plurality of first top power input contacts disposed on a top side of the insulating body, each of the first top power input contacts electrically connected to at least one of the top micro heaters;
a plurality of bottom power input contacts disposed on a bottom side of the insulating body, each of the bottom power input contacts electrically connected to at least one of the bottom micro heaters; and
a plurality of second top power input contacts disposed on the top side of the insulating body, each of the second top power input contacts electrically connected to the corresponding bottom power input contact through a conductive channel

7. An electronic device comprising a circuit substrate, an interposer board disposed on the circuit substrate, and at least one electronic chip been carried by the interposer board, the interposer board comprising:
an insulating body;
a plurality of top conductive contacts disposed on the insulating body;
a plurality of bottom conductive contacts disposed on the insulating body;
a plurality of conductive connection structures disposed on the insulating body, the conductive connection structures respectively electrically connected to the top conductive contacts and respectively electrically connected to the bottom conductive contacts; and
a plurality of micro heaters disposed on or in the insulating body, wherein the micro heaters are respectively adjacent to the top conductive contacts and the bottom conductive contacts;
wherein each of the top conductive contacts or each of the bottom conductive contacts is heated by the corresponding micro heater.

8. The electronic device according to claim 7, further comprising: a first non-conductive film and a second non-conductive film, the first non-conductive film is disposed between the insulating body and the circuit substrate, and the second non-conductive film is disposed between the at least one electronic chip and the insulating body; wherein the at least one electronic chip is electrically connected to the circuit substrate through the interposer board, and the first non-conductive film and the second non-conductive film are heated by the micro heaters; wherein the bottom conductive contacts are respectively electrically connected to a plurality of conductive substrate contacts of the circuit substrate respectively through the bottom solders, and the top conductive contacts are respectively electrically connected to a plurality of conductive chip contacts of the at least one electronic chip respectively through the top solders; wherein the conductive connection structure is a straight or non-straight conductive connection body, and the conductive connection structure has two opposite sides respectively electrically connected to the top conductive contact and the bottom conductive contact; wherein the micro heaters are divided into a plurality of top micro heaters and a plurality of bottom micro heaters, the top micro heater is closer to the at least one electronic chip than the bottom micro heater is, and the bottom micro heater is closer to the circuit substrate than the top micro heater is.

9. The electronic device according to claim 8, wherein the interposer board further comprises:
a plurality of first top power input contacts disposed on a top side of the insulating body, each of the first top power input contacts electrically connected to at least one of the top micro heaters;
a plurality of bottom power input contacts disposed on a bottom side of the insulating body, each of the bottom power input contacts electrically connected to at least one of the bottom micro heaters; and
a plurality of second top power input contacts disposed on the top side of the insulating body, each of the second top power input contacts electrically connected to the corresponding bottom power input contact through a conductive channel.

10. The electronic device according to claim 8, wherein a plurality of top solders are respectively disposed on the top conductive contacts, a plurality of bottom solders are respectively disposed on the bottom conductive contacts, and the top solders and the bottom solders are heated by the micro heaters.
